(19) United States
(12) Patent Application Publication
(10) Pub. No.: US 2014/0187043 A1
(43) Pub. Date: Jul. 3, 2014

(54) POLISHING AGENT AND POLISHING METHOD

(71) Applicant: ASAHI GLASS COMPANY, LIMITED, Chiyoda-ku (JP)

(72) Inventors: Iori YOSHIDA, Tokyo (JP); Satoshi TAKEMIYA, Tokyo (JP); Hiroyuki TOMONAGA, Tokyo (JP)

(73) Assignee: ASAHI GLASS COMPANY, LIMITED, Chiyoda-ku (JP)

(21) Appl. No.: 14/197,844

(22) Filed: Mar. 5, 2014

Related U.S. Application Data
(63) Continuation of application No. PCT/JP2012/071266, filed on Aug. 23, 2012.

(30) Foreign Application Priority Data
Sep. 5, 2011 (JP) 2011-192887

(51) Int. Cl. C09G 1/02; H01L 21/306

(52) U.S. Cl. CPC C09G 1/02; H01L 21/30625
USPC 438/693; 252/79.1

(57) ABSTRACT

A non-oxide single-crystal substrate such as a silicon carbide single-crystal substrate is polished at a high polishing rate, whereby a smooth surface is obtained. There is provided a polishing agent containing: an oxidant that contains a transition metal and has a redox potential of 0.5 V or more; silica particles that have an average secondary particle size of 0.2 μm or less; and a dispersion medium, wherein a content ratio of the oxidant is not less than 0.25 mass % nor more than 5 mass %, and a content ratio of the silica particles is not less than 0.01 mass % and less than 20 mass %.

### CROSS-REFERENCE TO RELATED APPLICATIONS

This application is a continuation of prior International Application No. PCT/JP2012/071266, filed on Aug. 23, 2012 which is based upon and claims the benefit of priority from Japanese Patent Application No. 2011-192887 filed on Sep. 5, 2011; the entire contents of all of which are incorporated herein by reference.

### TECHNICAL FIELD

The present invention relates to a polishing agent and a polishing method for chemical mechanical polishing a non-oxide single-crystal substrate. More particularly, it relates to a polishing agent suitable for polishing a silicon carbide single-crystal substrate or the like and a polishing method using the same.

### BACKGROUND ART

Since a silicon carbide (SiC) semiconductor is higher in dielectric breakdown field, saturation drift velocity of electrons, and heat conductivity than a silicon semiconductor, researches and developments for using the silicon carbide semiconductor to realize a power device capable of operating at a higher temperature and at a higher speed than conventional silicon devices have been made. Among them, the development of high-efficiency switching elements used for power sources for driving motors of an electric motorcycle, an electric vehicle, a hybrid car, and the like has been drawing attention. In order to realize such power devices, a silicon carbide single-crystal substrate with a smooth surface where to epitaxially grow a high-quality silicon carbide semiconductor layer is necessary.

Further, as a light source for high-density information recording, a blue laser diode has been drawing attention, and further a need for a white diode is increasing as a light source replacing a fluorescent light and an electric bulb. For the fabrication of such a light-emitting element, a gallium nitride (GaN) semiconductor is used, and as a substrate where to form a high-quality gallium nitride semiconductor layer, a silicon carbide single-crystal substrate is used.

For a silicon carbide single-crystal substrate for such a use, high processing precision is required in terms of flatness of the substrate, smoothness of a substrate surface, and so on. However, since a silicon carbide single-crystal has very high hardness and is excellent in corrosion resistance, its workability when the substrate is fabricated is poor, and it is difficult to obtain a silicon carbide single-crystal substrate having high smoothness.

Generally, a smooth surface of a semiconductor single-crystal substrate is formed by polishing. When a silicon carbide single-crystal is polished, its surface is mechanically polished to be formed into a flat surface by using abrasive grains of diamond or the like harder than silicon carbide as a polishing agent, but minute scratches according to a grain size of the diamond abrasive grains are introduced onto the surface of the silicon carbide single-crystal substrate polished by the diamond abrasive grains. Further, since an affected layer having a mechanical strain is generated on the surface, the surface of the silicon carbide single-crystal substrate is not smooth enough as it is.

In the manufacture of a semiconductor single-crystal substrate, as a method of smoothing the surface of the semiconductor substrate having been mechanically polished, a chemical mechanical polishing (hereinafter sometimes referred to as CMP) technique is used. CMP is a method to polish a surface by changing a workpiece into an oxide or the like with the use of a chemical reaction such as oxidation and by removing the generated oxide with the use of abrasive grains lower in hardness than the workpiece. This method has advantages of being capable of forming a very smooth surface without causing a strain on the surface of the workpiece.

As a polishing agent for smoothly polishing a surface of a silicon carbide single-crystal substrate by CMP, a polishing composition having pH of 4 to 9 and containing colloidal silica has been conventionally known (for example, refer to Patent Reference 1: JP-A 2005-117027 (KOKAI)). There has also been proposed a polishing composition containing silica abrasive grains, an oxidant (oxygen donor) such as hydrogen peroxide, and vanadate (for example, refer to Patent Reference 2: JP-A 2008-179655 (KOKAI)).

However, the polishing composition of Patent Reference 1 has a problem that a polishing rate for a silicon carbide single-crystal substrate is low, so that the time required for the polishing becomes very long. Further, the use of the polishing composition of Patent Reference 2 also has a problem that a polishing rate is not high enough, so that it takes a long time for the polishing.

### SUMMARY OF THE INVENTION

The present invention has been made to solve such problems, and its object is to provide a polishing agent and a polishing method for polishing a non-oxide single-crystal substrate having high hardness and high chemical stability such as a silicon carbide single-crystal substrate at a high polishing rate to obtain a smooth surface.

A polishing agent of the present invention is a polishing agent for chemical mechanical polishing a non-oxide single-crystal substrate containing an oxidant that contains a transition metal and has a redox potential of 0.5 V or more, silica particles that have an average secondary particle size of 0.2 μm or less, and a dispersion medium, wherein a content ratio of the oxidant is not less than 0.25 mass % nor more than 5 mass %, and a content ratio of the silica particles is not less than 0.01 mass % and less than 20 mass %.

In the polishing agent of the present invention, the oxidant is preferably a permanganate ion. Further, pH of the polishing agent of the present invention is preferably 11 or less, and more preferably 5 or less. The non-oxide single-crystal substrate is preferably a silicon carbide (SiC) single-crystal substrate or a gallium nitride (GaN) single-crystal substrate.

A polishing method of the present invention is a method comprising supplying the polishing agent of the present invention to a polishing pad, bringing a surface to be polished of a non-oxide single-crystal substrate being a polishing object into contact with the polishing pad, and polishing by a relative movement between the surface to be polished and the polishing pad.

According to the polishing agent of the present invention and the polishing method using the same, it is possible to polish a surface to be polished of a non-oxide single-crystal substrate having high hardness and high chemical stability such as a silicon carbide single-crystal substrate and a gallium nitride single-crystal substrate at a high polishing rate and to obtain a flat and smooth polished surface. Note that, in the present invention, “surface to be polished” is a surface, of the polishing object, that is to be polished, and means, for example, a front surface.

### BRIEF DESCRIPTION OF THE DRAWINGS

FIG. 1 is a diagram illustrating an example of a polishing apparatus capable of being used in an embodiment of the polishing method of the present invention.

### DETAILED DESCRIPTION

Hereinafter, embodiments of the present invention will be described.

### [Polishing Agent]

The polishing agent according to the embodiment of the present invention is a polishing agent for chemical mechanical polishing a non-oxide single-crystal substrate, and it contains, an oxidant that contains a transition metal and has a redox potential of 0.5 V or more, silica particles being abrasive grains that have an average secondary particle size of 0.2 μm or less, and a dispersion medium, and has a slurry state. A ratio of the content of the silica particles is not less than 0.01 mass % and less than 20 mass % to the entire polishing agent. Further, a content ratio of the oxidant is not less than 0.25 mass % nor more than 5 mass % to the entire polishing agent. Note that, in the description below, the polishing agent is sometimes referred to as a polishing liquid.

The polishing agent according to the embodiment of the present invention contains the oxidant having the redox potential of 0.5 V or more and containing the transition metal, the ratio of the oxidant being not less than 0.25 mass % nor more than 5 mass %, and contains the silica particles with the average secondary particle size of 0.2 μm or less whose ratio (concentration) is not less than 0.01 mass % and less than 20 mass % and thus is relatively low ratio, and therefore, it is possible to polish a surface to be polished of a polishing object having high hardness and high chemical stability such as a SiC single-crystal substrate at a high polishing rate and to obtain a flat and smooth surface.

In the polishing agent according to the embodiment of the present invention, pH of the polishing agent is preferably 11 or less. In order to adjust pH to 11 or less, a pH adjusting agent can be added. When pH of the polishing agent is 11 or less, the oxidant acts effectively, resulting in a good polishing property and excellent dispersion stability of the silica particles being the abrasive grains. Hereinafter, the components and pH of the polishing agent according to the embodiment of the present invention will be described in detail.

### (Oxidant)

The oxidant contained in the polishing agent according to the embodiment of the present invention forms an oxide layer on a surface to be polished of a later-described polishing object (for example, a SiC single-crystal substrate or a GaN single-crystal substrate). Removing this oxide layer from the surface to be polished by a mechanical force promotes the polishing of the polishing object. Specifically, a compound semiconductor such as SiC and GaN is a non-oxide and is a material hard to be polished, but the oxide layer can be formed on its surface by the oxidant in the polishing agent. The formed oxide layer is low in hardness compared with the polishing object and thus is easily polished, and therefore can be effectively removed by the silica particles being the abrasive grains. As a result, a high polishing rate can be obtained.

The oxidant contained in the polishing agent according to the embodiment of the present invention contains the transition metal and has the redox potential of 0.5 V or more. The oxidant containing the transition metal and having the redox potential of 0.5 V or more is preferably, for example, permanganate ion, vanadate ion, dichromate ion, ceric ammonium nitrate, iron (III) nitrate nonahydrate, silver nitrate, phosphotungstic acid, tungstosilicic acid, phosphomolybdic acid, phosphotungstomolybdic acid, phosphovanadomolybdic acid, and the like, and permanganate ion is especially preferable. As a supply source of permanganate ion, permanganate such as potassium permanganate or sodium permanganate is preferable.

Reasons why permanganate ion is especially preferable as the oxidant in the polishing of the SiC single-crystal substrate will be described below.
(1) Permanganate ion has a strong oxidizing power that oxidizes a SiC single-crystal. When the oxidizing power of the oxidant is too weak, the reaction with the surface to be polished of the SiC single-crystal substrate becomes insufficient, and as a result, a sufficiently smooth surface cannot be obtained. As an index of the oxidizing power by which the oxidant oxidizes a substance, a redox potential is used. Permanganate ion has 1.70 V redox potential and is higher in redox potential compared with potassium perchlorate (KClO₄) (redox potential is 1.20 V) and sodium hypochlorite (NaClO) (redox potential is 1.63 V) which are generally used as an oxidant.
(2) The reaction rate of permanganate ion is high.

Being higher in the reaction rate of the oxidation reaction compared with hydrogen peroxide (redox potential is 1.76 V) known as an oxidant having a strong oxidizing power, permanganate ion can quickly exhibit the strong oxidizing power.
(3) Permanganate ion has a low environmental load.
(4) Permanganate completely dissolves in a later-described dispersion medium (water). Therefore, there occurs no adverse effect of a dissolution residue on smoothness of the substrate.

In order to obtain the effect of improving the polishing rate, a content ratio (concentration) of permanganate ion in the polishing agent is preferably not less than 0.25 mass % nor more than 5 mass %. When its content ratio is less than 0.25 mass %, the effect as the oxidant cannot be expected, and it may take a very long time to form a smooth surface by polishing or scratches may be generated on the surface to be polished. When the content ratio of permanganate ion is more than 5 mass %, permanganate is not completely dissolved to precipitate depending on the temperature of the polishing liquid, which involves a concern that scratches are generated due to the contact of solid permanganate with the surface to be polished. The content ratio of permanganate ion contained in the polishing agent is more preferably not less than 0.5 mass % nor more than 5 mass %, and especially preferably not less than 1 mass % nor more than 5 mass %.

### (Silica Particles)

As the polishing abrasive grains, the polishing agent according to the embodiment of the present invention contains the silica particles with the average secondary particle size of 0.2 μm or less whose ratio (concentration) is not less than 0.01 mass % and less than 20 mass %. The average secondary particle size of the silica particles is more preferably 0.15 μm or less. Examples of the silica particles having such an average secondary particle size are colloidal silica, fumed silica (also called aerosol silica), and the like.

In the polishing of the SiC single-crystal substrate, when the polishing agent which contains, in addition to the aforesaid oxidant, the silica particles whose ratio is not less than 0.01 mass % and less than 20 mass % is used, it is possible to obtain a smooth surface for which the polishing rate is higher and whose surface roughness is smaller than when a polishing agent containing the silica particles whose concentration is higher is used.

Further, when silica particles whose average secondary particle size is over the aforesaid range are used as the abrasive grains, a damage given to the surface to be polished of the SiC single-crystal substrate becomes great and it is not possible to obtain a smooth, high-quality surface.

Note that the silica particles contained as the abrasive grains generally exist in the polishing agent as aggregated particles (secondary particles) resulting from the aggregation of primary particles, and therefore, the preferable particle size of the silica particles is expressed by the average secondary particle size (average aggregated particle size). The average secondary particle size is an average value of diameters of the silica secondary particles in the polishing agent, and is measured by using, for example, a particle size distribution analyzer using dynamic light scattering. An average value of the primary particle sizes (average primary particle size) of the silica particles preferably falls within a range of 5 nm to 150 nm in view of polishing property and dispersion stability. Here, the average primary particle size is found as a sphere-equivalent particle size from specific surface areas of the particles, for instance. The specific surface areas of the particles are measured by a nitrogen absorption method known as a BET method.

The content ratio (concentration) of the silica particles in the polishing agent according to the embodiment of the present invention is set to not less than 0.01 mass % and less than 20 mass % in order to obtain a sufficient polishing rate. When the content ratio of the silica particles is less than 0.01 mass %, it is difficult to obtain a sufficient polishing rate. When it is 20 mass % or more, the polishing rate greatly lowers, which is not preferable either. A more preferable content ratio is from 0.05 mass % to 15 mass %, and a still more preferable content ratio is from 0.1 mass % to 10 mass %.

### (pH and pH Adjusting Agent)

pH of the polishing agent according to the present invention is preferably 11 or less, more preferably 5 or less, and especially preferably 3 or less in view of polishing property and dispersion stability of the silica particles being the abrasive grains. When pH is more than 11, not only a sufficient polishing rate is not obtained but also smoothness of the surface to be polished is liable to deteriorate.

pH of the polishing agent can be adjusted by the addition and compounding of acid or a basic compound being a pH adjusting agent. As the acid, usable are inorganic acid such as nitric acid, sulfuric acid, phosphoric acid, and hydrochloric acid, saturated carboxylic acid such as formic acid, acetic acid, propionic acid, and butyric acid, hydroxy acid such as lactic acid, malic acid, and citric acid, aromatic carboxylic acid such as phthalic acid and salicylic acid, dicarboxylic acid such as oxalic acid, malonic acid, succinic acid, glutaric acid, adipic acid, fumaric acid, and maleic acid, and an organic acid such as amino acid and heterocyclic carboxylic acid. Nitric acid or phosphoric acid is preferably used, and above all, the use of nitric acid is especially preferable. As the basic compound, usable are inorganic alkali such as ammonia, lithium hydroxide, potassium hydroxide, and sodium hydroxide, quaternary ammonium compounds such as tetramethylammonium, and organic amine such as monoethanolamine, ethylethanolamine, diethanolamine, and propylene diamine. The use of potassium hydroxide or sodium hydroxide is preferable, and potassium hydroxide is especially preferable.

A content ratio (concentration) of the above acid or basic compound is set to an amount so that pH of the polishing agent is adjusted to the predetermined range (pH 11 or less, more preferably 5 or less).

### (Dispersion Medium)

In the polishing agent according to the embodiment of the present invention, water is contained as the dispersion medium. Water is a medium for stably dispersing the silica particles and for dispersing or dissolving the oxidant and later-described optional components added when necessary. Water is not particularly limited, but pure water, ultrapure water, and ion-exchange water (deionized water) are preferable in view of an influence on the compounded components, the contamination of impurities, an influence on pH, and the like.

### (Preparation of Polishing Agent and Arbitrary Components)

When in use, the polishing agent according to the embodiment of the present invention is prepared so that it contains the predetermined ratios of the aforesaid components, the silica particles uniformly disperse therein, and the other components are in a mixed state of being uniformly dissolved. For the mixture, a stirring and mixing method generally used for the manufacture of polishing agents, for example, a stirring and mixing method by an ultrasonic dispersion machine, a homogenizer, or the like is adoptable. The polishing agent according to the present invention does not necessarily have to be supplied to a polishing site as a mixture in which the constituent polishing components are all mixed in advance. The polishing components may be mixed to form the composition of the polishing agent at the time of the supply to the polishing site.

The polishing agent according to the embodiment of the present invention can appropriately contain an aggregation preventing or dispersing agent (hereinafter, referred to as a dispersing agent), a lubricant, a chelating agent, a reducing agent, a viscosity imparting agent or a viscosity adjusting agent, an antirust, and so on as required without departing from the spirit of the present invention. Note that, when these additives have a function of the oxidant, the acid, or the basic compound, they are treated as the oxidant, the acid, or the basic compound.

The dispersing agent is added in order to stably disperse the silica particles being the abrasive grains in the dispersion medium such as pure water. Further, the lubricant moderately adjusts a polishing stress occurring between the polishing object and the polishing agent to enable stable polishing. As the dispersing agent, an anionic, cationic, nonionic, or amphoteric surfactant and a water-soluble polymer having a surface-active action are usable. Further, as the lubricant, an anionic, cationic, nonionic, or amphoteric surfactant, a polysaccharide, a water-soluble polymer, and so on are usable.

Here, as the surfactant, usable is one that has an aliphatic hydrocarbon group and an aromatic hydrocarbon group as hydrophobic groups, with one or more of a bond group such as ester, ether, and amide and a linking group such as an acyl group and an alkoxyl group being introduced into these hydrophobic groups, and that has carboxylic acid, sulfonic acid, sulfate ester, phosphoric acid, phosphoric ester, and amino acid as hydrophilic groups.

As the polysaccharides, usable are alginic acid, pectin, carboxymethyl cellulose, curdlan, pullulan, xanthan gum, carrageenan, gellan gum, locust bean gum, gum arabic, tamarind, psyllium, and so on.

As the water-soluble polymer, usable are polyacrylic acid, polyvinyl alcohol, polyvinylpyrrolidone, polymethacrylic acid, polyacrylamide, polyaspartic acid, polyglutamic acid, polyethyleneimine, polyallylamine, polystyrene sulfonic acid, and the like. When the dispersing agent and the lubricant are used, their content ratios each preferably fall within a range of 0.001 mass % to 5 mass % to the total mass of the polishing agent.

### [Polishing Object]

The polishing object to be polished by using the polishing agent according to the embodiment of the present invention is a non-oxide single-crystal substrate. Examples of the non-oxide single-crystal substrate are compound semiconductor substrates such as a SiC single-crystal substrate and a GaN single-crystal substrate. The use of the polishing agent according to the embodiment of the present invention for polishing especially a single-crystal substrate whose modified Mohs hardness is 10 or more, such as the aforesaid SiC single-crystal substrate and GaN single-crystal substrate makes it possible to further obtain the effect of the high-speed polishing.

### [Polishing Method]

As a method for polishing the non-oxide single-crystal substrate being the polishing object by using the polishing agent according to the embodiment of the present invention, a method in which the polishing agent is supplied to a polishing pad, the surface to be polished of the polishing object and the polishing pad are brought into contact, and the polishing is performed by a relative movement between both is preferable.

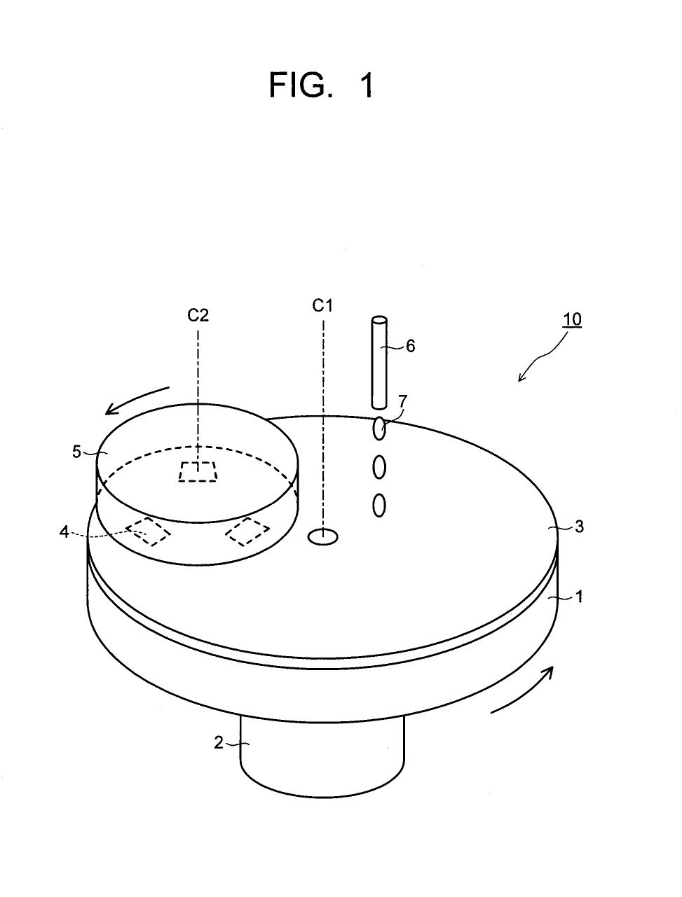

In the aforesaid polishing method, a conventionally known polishing apparatus can be used. FIG. 1 shows an example of the polishing apparatus usable in the embodiment of the present invention, but the polishing apparatus used for the embodiment of the present invention is not limited to one having such a structure.

The polishing apparatus 10 shown in FIG. 1 is provided with a polishing platen 1 which is supported to be rotatable around its vertical axis C Land the polishing platen 1 is driven to rotate in the direction indicated by the arrow in the drawing by a platen driving motor 2. On an upper surface of this polishing platen 1, a well-known polishing pad 3 is affixed.

On the polishing platen 1, at a position eccentric from the axis C1, a substrate holding member (carrier) 5 for holding a object 4 to be polished such as a SiC single-crystal substrate on its lower surface by using suction, a holding frame, or the like is supported to be rotatable around its axis C2 and to be movable in a direction along the axis C2. The substrate holding member 5 is rotated in the direction indicated by the arrow by a not-shown carrier driving motor or by a rotational moment received from the aforesaid polishing platen 1. On the lower surface of the substrate holding member 5, that is, on its surface facing the aforesaid polishing pad 3, the object 4 to be polished is held. The object 4 to be polished is pressed against the polishing pad 3 by a predetermined load.

Near the substrate holding member 5, a dripping nozzle 6 or the like is provided, so that the polishing agent (hereinafter, also referred to as the polishing liquid) 7 according to the embodiment of the present invention fed from a not-shown tank is supplied onto the polishing platen 1.

At the time of the polishing by such a polishing apparatus 10, the polishing platen 1 and the polishing pad 3 affixed thereon, and the substrate holding member 5 and the object 4 to be polished supported on the its lower surface are driven to rotate around their axes by the platen driving motor 2 and the work driving motor, respectively. Then, in this state, the polishing agent 7 is supplied from the dripping nozzle 6 or the like to the surface of the polishing pad 3, and the object 4 to be polished held by the substrate holding member 5 is pressed against the polishing pad 3. Consequently, the surface to be polished of the object 4, that is, its surface facing the polishing pad 3, is chemically and mechanically polished.

The substrate holding member 5 may perform not only the rotational movement but also a linear movement. Further, the polishing platen 1 and the polishing pad 3 may not be performing the rotational movement, and for example, may move in one direction by a belt system.

As the polishing pad 3, the one made up of a nonwoven fabric, a porous resin such as polyurethane foam, a nonporous resin, and the like can be used. The polishing pad 3 is preferable the one which does not contain the abrasive grains. Further, to accelerate the supply of the polishing liquid 7 to the polishing pad 3 or to allow a certain amount of the polishing liquid 7 to stay in the polishing pad 3, the surface of the polishing pad 3 may be worked to have a groove in a lattice shape, a concentric shape, a spiral shape, or the like. Further, when necessary, a pad conditioner may be brought into contact with the surface of the polishing pad 3 to polish while conditioning the surface of the polishing pad 3.

A condition of the polishing by such a polishing apparatus 10 is not particularly limited, but it is possible to more increase a polishing pressure and improve the polishing rate by applying a load to the substrate holding member 5 to press it against the polishing pad 3. The polishing pressure is preferably about from 5 kPa to 80 kPa, and in view of uniformity of the polishing rate in the surface to be polished, flatness of the surface to be polished, and the prevention of a polishing defect such as a scratch, the polishing pressure is more preferably about from 10 kPa to 50 kPa. The rotation speed of the polishing platen 1 and the substrate holding member 5 is preferably about from 50 rpm to 500 rpm but is not limited thereto. Further, a supply amount of the polishing liquid 7 is appropriately adjusted and selected according to a constitution material of the surface to be polished, the composition of the polishing liquid, the aforesaid polishing condition, and so on.

### Examples

Hereinafter, the present invention will be concretely described based on working examples and comparative examples, but the present invention is not limited to these examples. Examples 1 to 21 are the working examples of the present invention, and examples 22 to 29 are the comparative examples.

### (1) Preparation of Polishing Agent

(1-1)

A polishing agent of the example 1 was prepared as follows. Pure water was added to a potassium permanganate powder being an oxidant, followed by ten-minute stirring. Next, a colloidal silica dispersion was added, followed by three-minute stirring, and nitric acid being a pH adjusting agent was gradually added to adjust the concentration of potassium permanganate and the concentration of abrasive grains to predetermined values shown in Table 1, and adjust pH to a value shown in Table 2, whereby a polishing agent was obtained. In the working examples of the examples 2 to 21 as well, polishing agents described in Table 1 and Table 2 were prepared by the same method as that of the example 1. Note that the concentration of the oxidant in Table 1 is not the concentration of permanganate ion but is the concentration of potassium permanganate.

(1-2)

Polishing agents of the examples 22 to 29 were prepared as follows. In the example 22, pure water was added to a colloidal silica dispersion, followed by ten-minute stirring, next, ammonium vanadate was added as metallic salt to this liquid while stirring, and finally, hydrogen peroxide was added, followed by thirty-minute stirring, whereby the polishing agents whose component concentrations were adjusted to the predetermined concentrations shown in Table 1 and Table 2 were obtained. Regarding the examples 23 to 25 and the example 29, the same method as that of the example 1 was used for the preparation, whereby the polishing agents whose component concentrations were adjusted to the concentrations described in Table 1 and Table 2 were obtained. Regarding the examples 26 to 28, pure water was added to a colloidal silica dispersion, followed by ten-minute stirring, and next, nitric acid being a pH adjusting agent was gradually added to this liquid, whereby the polishing agents whose component concentrations were adjusted to the predetermined concentrations shown in Table 1 and Table 2 were obtained.

Note that secondary particle sizes of silica particles compounded in the examples 1 to 29 were measured by “Microtrack UPA” (manufactured by Nikkiso Co., Ltd.).

### (2) Measurement of pH

pH of the polishing agents obtained in the examples 1 to 29 was measured at 25° C. by using “pH81-11” manufactured by Yokogawa Electric Corporation. The measurement results are shown in Table. 2.

### (3) Polishing Property

By using the polishing agents obtained in the examples 1 to 29, polishing was performed under the conditions described blow.

### (3-1) Polishing Conditions

As a polishing machine, a small-size polishing apparatus manufactured by MAT Inc. was used. As a polishing pad, “SUBA800-XY-groove” (manufactured by Nitta Haas

Incorporated) was used, and the five-minute conditioning of the polishing pad was performed by using a diamond disk and a brush before the polishing. A feeding rate of the polishing agents was set to 25 cm³/minute, the rotation speed of the polishing platen was set to 68 rpm, the rotation speed of the substrate holding member was set to 68 rpm, the polishing pressure was set to 5 psi (34.5 kPa), and the polishing was performed for thirty minutes.

### (3-2) Polishing Object

As polishing objects, 4H-SiC substrates with a 3 inch diameter having undergone a preliminary polishing process using diamond abrasive grains were used. By using SiC single-crystal substrates whose off-angle from a C axis of a main surface (0001) was within 4°±0.5° (hereinafter, referred to as 4-degree off substrates), Si surface sides were polished and a polishing property (polishing rate) was evaluated.

### (3-3) Measurement of Polishing Rate

The polishing rate was evaluated based on an amount (nm/hr) of change in thickness of each of the SiC single-crystal substrates per unit time. Specifically, a mass of each of the unpolished substrates with a known thickness and a mass of each of the substrates after polished for each period of time were measured, and the mass change was determined from the difference between them. Further, the change in thickness of the substrates determined from the mass change per period of time was calculated using the following formulas. The calculation results of the polishing rate are shown in Table 2.

### (Formulas for Calculating Polishing Rate (V))

Δm=m0−m1

V=Δm/m0×T0×60 /t

(in the formulas, Δm(g) represents the mass change between before and after the polishing, m0(g) represents the initial mass of the unpolished substrate, m1(g) represents the mass of the substrate after polished, V represents the polishing rate (nm/hr), T0 represents the thickness (nm) of the unpolished substrate, and t represents the polishing time (min)).

TABLE 1

| | | | Secondary | | |
|---|---|---|---|---|---|
| | | Concentration | Particle | | |
| | | of | Size of | | Concentration |
| | Kind of | Abrasive | Abrasive | Kind | of |
| | Abrasive | Grains | Grains | of | Oxidant |
| | Grains | (mass %) | (μm) | Oxidant | (mass %) |
| E1 | colloidal silica | 10 | 0.07 | potassium permanganate | 3.16 |
| E2 | colloidal silica | 10 | 0.07 | potassium permanganate | 3.16 |
| E3 | colloidal silica | 15 | 0.07 | potassium permanganate | 1.58 |
| E4 | colloidal silica | 15 | 0.07 | potassium permanganate | 0.5 |
| E5 | colloidal silica | 0.1 | 0.07 | potassium permanganate | 1.58 |
| E6 | colloidal silica | 0.1 | 0.07 | potassium permanganate | 0.3 |
| E7 | colloidal silica | 0.1 | 0.07 | potassium permanganate | 3.16 |
| E8 | colloidal silica | 0.1 | 0.07 | potassium permanganate | 5 |
| E9 | colloidal silica | 0.1 | 0.07 | potassium permanganate | 3.16 |
| E10 | colloidal silica | 0.1 | 0.07 | potassium permanganate | 3.16 |
| E11 | colloidal silica | 0.1 | 0.12 | potassium permanganate | 3.16 |
| E12 | colloidal silica | 0.1 | 0.02 | potassium permanganate | 3.16 |
| E13 | colloidal silica | 0.1 | 0.01 | potassium permanganate | 3.16 |
| E14 | colloidal silica | 0.1 | 0.11 | potassium permanganate | 3.16 |
| E15 | colloidal silica | 0.1 | 0.04 | potassium permanganate | 3.16 |
| E16 | colloidal silica | 0.1 | 0.07 | potassium permanganate | 3.16 |
| E17 | colloidal silica | 0.1 | 0.05 | potassium permanganate | 3.16 |
| E18 | fumed silica | 0.1 | 0.15 | potassium permanganate | 3.16 |
| E19 | colloidal silica | 1 | 0.07 | potassium permanganate | 1.58 |
| E20 | colloidal silica | 5 | 0.07 | potassium permanganate | 1.58 |
| E21 | colloidal silica | 18 | 0.07 | potassium permanganate | 1.58 |
| E22 | colloidal silica | 20 | 0.07 | hydrogen peroxide | 1 |
| E23 | colloidal silica | 20 | 0.11 | potassium permanganate | 1.58 |
| E24 | colloidal silica | 20 | 0.11 | potassium permanganate | 1.58 |
| E25 | colloidal silica | 20 | 0.11 | potassium permanganate | 1.58 |
| E26 | colloidal silica | 10 | 0.11 | — | — |
| E27 | colloidal silica | 1 | 0.11 | — | — |
| E28 | colloidal silica | 0.1 | 0.11 | — | — |
| E29 | colloidal silica | 0.1 | 0.07 | potassium permanganate | 0.2 |

TABLE 2

| | | | | | Polishing |
|---|---|---|---|---|---|
| | | | | | Rate for |
| | | | | | 4-degree |
| | | Cocentration | pH | | Off |
| | Kind of | of Metallic | Adjusting | | Substrate |
| | Metallic Salt | Salt (mass %) | Agent | pH | (nm/hr) |
| E1 | — | — | nitric acid | 2 | 1101 |
| E2 | — | — | nitric acid | 5 | 935 |
| E3 | — | — | nitric acid | 2 | 743 |
| E4 | — | — | nitric acid | 2 | 206 |
| E5 | — | — | phosphoric acid | 2 | 319 |
| E6 | — | — | nitric acid | 2 | 165 |
| E7 | — | — | nitric acid | 2 | 1169 |
| E8 | — | — | nitric acid | 2 | 1431 |
| E9 | — | — | nitric acid | 5 | 509 |
| E10 | — | — | KOH | 11 | 275 |
| E11 | — | — | nitric acid | 2 | 1128 |
| E12 | — | — | nitric acid | 2 | 1004 |
| E13 | — | — | nitric acid | 2 | 949 |
| E14 | — | — | nitric acid | 2 | 1087 |
| E15 | — | — | nitric acid | 2 | 1032 |
| E16 | — | — | nitric acid | 2 | 1073 |
| E17 | — | — | nitric acid | 2 | 1087 |
| E18 | — | — | nitric acid | 2 | 1087 |
| E19 | — | — | nitric acid | 2 | 783 |
| E20 | — | — | nitric acid | 2 | 713 |
| E21 | — | — | nitric acid | 2 | 503 |
| E22 | ammonium | 0.5 | — | 6.5 | 83 |
| | vanadate | | | | |
| E23 | — | — | phosphoric acid | 2 | 28 |
| E24 | — | — | nitric acid | 2 | 69 |
| E25 | — | — | — | 8 | 83 |
| E26 | — | — | nitric acid | 2 | 10 |
| E27 | — | — | nitric acid | 2 | 0 |
| E28 | — | — | nitric acid | 2 | 0 |
| E29 | — | — | nitric acid | 2 | 84 |

As is understood from Table 2, when the polishing agents of the examples 1 to 21 are used, a high polishing rate is obtained for the SiC single-crystal substrate whose off-angle is within 4°±0.5°, and high-speed polishing is possible. Further, flaws ascribable to the polishing are not generated on the surface to be polished of the SiC single-crystal substrate being the polishing object, and it is possible to obtain a surface excellent in flatness and smoothness.

On the other hand, in the polishing agent of the example 22, since it contains hydrogen peroxide instead of potassium permanganate as the oxidant, the polishing rate for the SiC single-crystal substrate is lower than those of the examples 1 to 21. Further, in the polishing agents of the examples 23 to 25, since the content ratio (concentration) of colloidal silica being the abrasive grains is 20 mass % or more and thus falls out of the range of the present invention, the polishing rate is far lower compared with those of the examples 1 to 21. Further, in the polishing agent of the example 29, since the content ratio (concentration) of potassium permanganate being the oxidant is 0.2 mass % and thus falls out of the range of the present invention, the polishing rate is far lower compared with those of the examples 1 to 21. Further, in the polishing agents of the examples 26 to 28, since potassium permanganate being the oxidant is not contained, the polishing rate for the SiC single-crystal substrate is 0 (zero) or near 0 (zero) and thus is remarkably low.

According to the polishing agent of the present invention, it is possible to polish, at a high speed, non-oxide single-crystal substrates, in particular, compound semiconductor substrates having high hardness and high chemical stability such as a SiC single-crystal substrate and a GaN single-crystal substrate and to obtain a polished surface free from flaws and excellent in flatness and smoothness. Therefore, it is possible to contribute to productivity of these substrates.

What is claimed is:

1. A polishing agent for chemical mechanical polishing a non-oxide single-crystal substrate comprising:
an oxidant containing a transition metal and having a redox potential of 0.5 V or more;
silica particles having an average secondary particle size of 0.2 μm or less; and
a dispersion medium,
wherein a content ratio of the oxidant is not less than 0.25 mass % nor more than 5 mass %, and a content ratio of the silica particles is not less than 0.01 mass % and less than 20 mass %.

2. The polishing agent according to claim 1,
wherein the oxidant is a permanganate ion.

3. The polishing agent according to claim 1,
wherein pH of the polishing agent is 11 or less.

4. The polishing agent according to claim 3,
wherein pH of the polishing agent is 5 or less.

5. The polishing agent according to claim 1,
wherein the non-oxide single-crystal substrate is a silicon carbide (SiC) single-crystal substrate or a gallium nitride (GaN) single-crystal substrate.

6. A polishing method comprising:
supplying the polishing agent according to claim 1 to a polishing pad;
bringing a surface to be polished of a non-oxide single-crystal substrate being a polishing object into contact with the polishing pad; and
polishing by a relative movement between the surface to be polished and the polishing pad.
